(19) United States
(12) Patent Application Publication
(10) Pub. No.: US 2009/0029546 A1
(43) Pub. Date: Jan. 29, 2009

(54) METHOD FOR FORMING METAL LINES OF SEMICONDUCTOR DEVICE

(75) Inventor: Chang Hee Lee, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/181,228

(22) Filed: Jul. 28, 2008

(30) Foreign Application Priority Data
Jul. 26, 2007 (KR) 10-2007-0075132

(51) Int. Cl. H01L 21/768

(52) U.S. Cl. 438/653; 257/E21.584

(57) ABSTRACT

Methods are disclosed for forming metal lines of a semiconductor device that can reduce interconnection or contact resistance, and can reduce defects in a barrier metal layer having a column structure. The method can include forming a first metal line on a semiconductor substrate, forming an insulating film on the first metal line, forming a contact hole in the insulating film, sequentially forming a barrier metal layer and a capping layer for protecting the barrier metal layer on an entire upper surface of the resultant substrate, oxidizing the capping layer to form a capping oxide film, depositing a contact metal material on the resultant substrate, planarizing the contact metal material to expose the insulating film, and forming a second metal line on the insulating film.

### CROSS-REFERENCE TO RELATED APPLICATION

This application claims priority under the Paris Convention for the Protection of Industrial Property to Korean Patent Application No. 10-2007-0075132, filed Jul. 26, 2007, the contents of which are hereby incorporated by reference herein.

### BACKGROUND OF THE INVENTION

1. Field of the Invention

The present invention relates to semiconductor devices. More particularly to methods for forming metal lines of a semiconductor device, and the semiconductor devices manufactured by such methods.

2. Discussion of the Related Art

In general, semiconductor devices have experienced a trend of high-integration. The presence of multilayer metal lines and smaller contact holes in these highly-integrated semiconductor devices has caused an increase in contact resistance and defects. As a result, the reliability of conventional semiconductor devices has decreased.

One example of a conventional method for forming multilayer metal lines in a highly-integrated semiconductor device uses a tungsten plug. Typically, this tungsten plug method forms a titanium film in the contact hole by a sputtering method. Further, in this particular conventional method, tungsten is buried in the contact hole by a chemical vapor deposition (CVD) method after a barrier metal film made of titanium nitride is formed to enhance the bond between the titanium film and the tungsten layer. Also, a tungsten plug is formed by etching the tungsten layer such that the tungsten layer remains only in the contact hole.

One drawback of this particular conventional method is that the barrier metal layer cannot be formed to have the same thickness as the pattern of the finer contact hole. Another drawback of this particular method is that a defect forms in the barrier metal layer.

Typically, this tungsten plug method uses a general barrier metal layer having a column structure. For example, as shown in FIG. 1, a barrier metal layer 2 deposited on an insulating film or a metal material 1 typically includes titanium (Ti) and titanium nitride (TiN). When a metal material such as aluminum (Al) and tungsten is deposited on the barrier metal layer 2, the metal material infiltrates into the barrier metal layer 2 to cause a defect in the column structure of the barrier metal layer 2. This defect reduces the reliability of the semiconductor device because of increased contact resistance in the barrier metal layer.

### SUMMARY OF EXAMPLE EMBODIMENTS

In general, embodiments of the present invention relate to semiconductor devices, and methods for forming metal lines in semiconductor devices, that improve the reliability of the semiconductor devices. Advantageously, the disclosed teachings can result in a reduction of interconnection or contact resistance in a barrier metal layer. Further, the disclosed teachings can result in a minimization of defects in a barrier metal layer having a column structure.

In one embodiment, a method for forming metal lines in a semiconductor device includes forming a first metal line on a semiconductor substrate, forming an insulating film on the first metal line, forming a contact hole in the insulating film, sequentially forming a barrier metal layer and a capping layer on an upper surface of the resultant substrate, oxidizing the capping layer to form a capping oxide film, depositing a contact metal material on the resultant substrate, planarizing the contact metal material to expose the insulating film, and forming a second metal line on the insulating film.

In some embodiments, the contact hole can be formed by forming a pattern of the contact hole. The contact hole can be formed with reactive ion etching (RIE) that uses a pattern as a mask to perform anisotropic etching and coats a photoresist on the insulating film. The barrier metal layer can have at least one of a double structure of a titanium (Ti)/titanium nitride (TiN) film and a titanium nitride (TiN) film. The capping layer can be formed of titanium (Ti) to have a thickness of about 20 Å by a sputtering method. The capping layer can be oxidized by an oxygen (O₂) gas. The contact metal material can be at least one of copper (Cu), tungsten (W) and aluminum (Al).

This summary is provided to introduce a selection of concepts in a simplified form that are further described below in the detailed description. This summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 illustrates a conventional column structure of a general barrier metal layer;

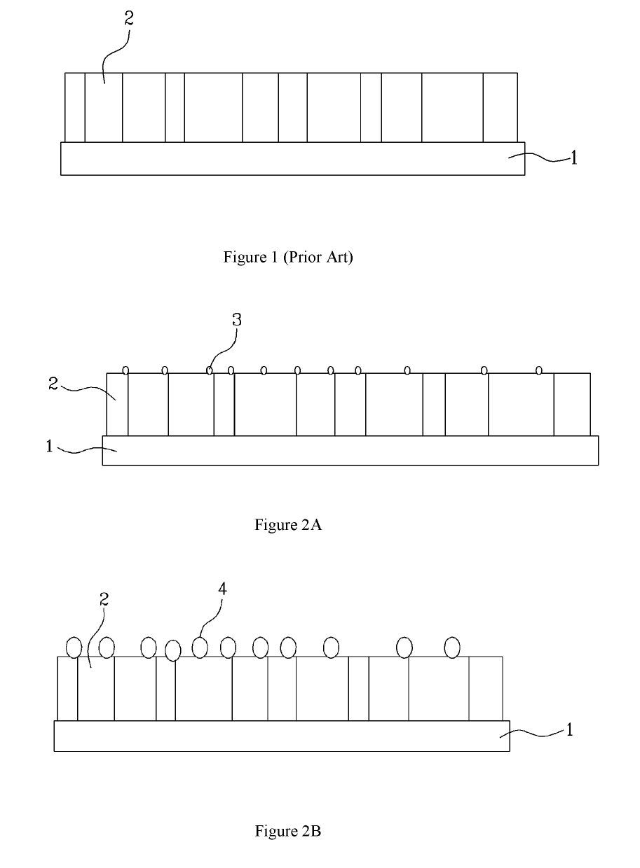

FIGS. 2A and 2B illustrate a method for forming a capping layer on a barrier metal layer having a column structure according to an example embodiment of the present invention;

FIGS. 3A to 3D depict cross-sectional views illustrating a method for forming metal lines of a semiconductor device according to an example embodiment of the present invention;

FIG. 4 provides a graph showing sheet resistance of a tungsten film; and

FIG. 5 provides a graph showing test results of a contact hole.

### DETAILED DESCRIPTION OF EXAMPLE EMBODIMENTS

In the following detailed description of the embodiments, reference will now be made in detail to specific embodiments of the present invention, examples of which are illustrated in the accompanying drawings. Whenever possible, the same reference numbers will be used throughout the drawings to refer to the same or like parts. These embodiments are described in sufficient detail to enable those skilled in the art to practice the invention. Other embodiments may be utilized without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

In general, embodiments of the present invention are directed to improving the reliability of a semiconductor device. In disclosed embodiments, forming a barrier metal layer in the vicinity of the contact hole reduces contact resistance in the contact hole. In this way, semiconductor device reliability is increased through reduced contact resistance. In disclosed embodiments, forming a capping layer on the barrier metal layer to protect the barrier metal layer improves a barrier metal layer by reducing defects in the barrier metal layer. As a result, the semiconductor device is more reliable as defects in the barrier metal layer are reduced.

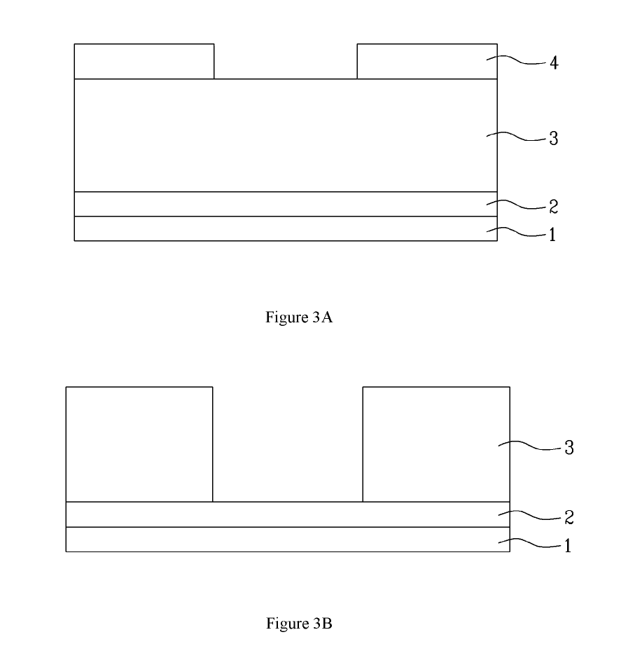

FIGS. 2A and 2B illustrate a method for forming a capping layer on a barrier metal layer having a column structure according to an example embodiment. Referring to FIG. 2A, a capping layer 3 is formed on a barrier metal layer 2 having a column structure. The capping layer 3 can be deposited on an insulating film or a metal material 1. The capping layer 3 prevents metal loss of the barrier metal layer 2 and prevents an increase in contact resistance. In this example, the capping layer 3 is deposited by a sputtering method, and is formed of particles or a thin film.

In this embodiment, the barrier metal layer 2 has at least one of a double structure of a titanium (Ti)/titanium nitride (TiN) film or a titanium nitride (TiN) film. Further, the capping layer 3 is formed of titanium (Ti) to have a thickness of about 20 Å by the sputtering method.

Referring to FIG. 2B, the capping layer 3 (not shown, see FIG. 2A) is then oxidized to form a capping oxide film 4. In the illustrated example, the capping oxide film 4 is a Ti oxide film formed by oxidizing a titanium film serving as the capping layer 3 using oxygen (O₂). As shown in the illustrated example, the capping oxide film 4 expands by the combination with oxygen to close gaps in the column structure of the barrier metal layer 2. Accordingly, it is possible to prevent infiltration of WF₆ gas and SiH₄ gas. Further, unoxidized titanium produces TiW to facilitate growth of tungsten grains, thereby producing a tungsten film having improved resistivity.

In one example, the column structure of a titanium nitride film is used as a general barrier metal layer in a conventional method. It will be appreciated that there can be gaps between grains.

In one embodiment, a grain structure of tungsten is deposited on a general barrier metal layer according to conventional methods. When tungsten is deposited on a general barrier metal layer, it can be seen that tungsten infiltrates into gaps in the column structure of the titanium nitride film formed under the tungsten layer.

A capping layer can be formed on the barrier metal layer by oxidizing a titanium film according to an example embodiment. Generally, when tungsten is deposited on the capping layer, the tungsten is not influenced by the titanium nitride film having the column structure formed under the tungsten layer. The oxidized titanium film is used as a capping layer to close gaps in the column structure of the titanium nitride film formed there under, thereby preventing the tungsten from infiltrating into gaps between the grains of the titanium nitride film having the column structure.

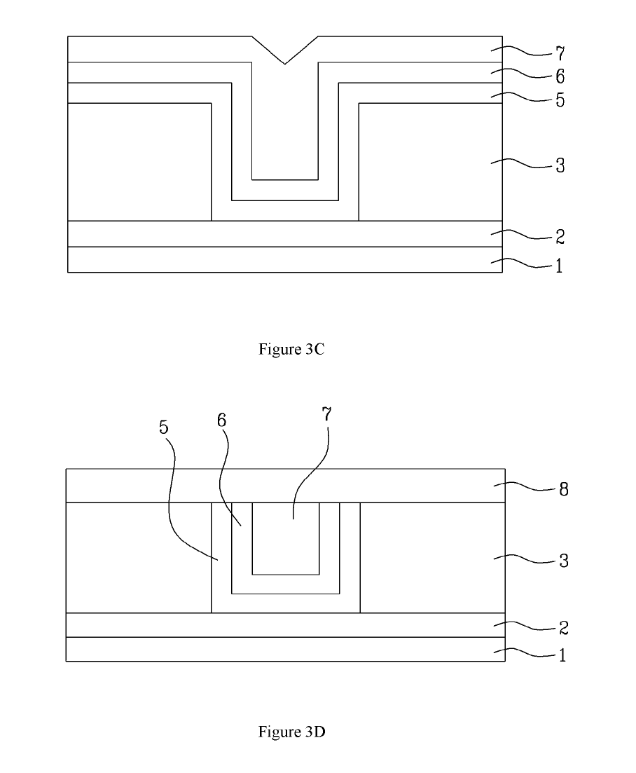

FIGS. 3A to 3D provide cross-sectional views showing the steps of a method for forming metal lines of a semiconductor device according to an embodiment of the present invention. Referring to FIG. 3A, a first metal line 2 and an insulating film 3 are sequentially formed on a semiconductor substrate 1 to form multilayer metal lines in the illustrated embodiment. Next, a photoresist is coated on the insulating film 3. Then, a photoresist pattern 4 is formed using a mask for forming a contact hole.

Referring to FIG. 3B, the insulating film 3 is then etched to expose the first metal line 2 using the photoresist pattern 4 (see FIG. 3A) as a mask. In the illustrated embodiment, the etching is reactive ion etching (RIE) to perform anisotropic etching. As shown in FIG. 3B, next the photoresist pattern 4 shown in FIG. 3A is removed. In this embodiment, the photoresist pattern 4 is removed through an ashing and cleaning process.

Referring to FIG. 3C, a barrier metal layer 5 and a capping layer 6 are then formed on the entire upper surface of the resultant substrate. Next, a metal material is deposited to gap-fill the contact hole. Next, the barrier metal layer 5 is formed on the resultant substrate. In the illustrated embodiment, the barrier metal layer 5 has a double structure of a titanium (Ti)/titanium nitride (TiN) film or is formed of only a titanium nitride (TiN) film. Also, the barrier metal layer 5 is formed to have a column structure.

Next, the capping layer 6 is formed on the barrier metal layer 5. The capping layer can be formed of titanium (Ti) to have a thickness of about 20 Å by a sputtering method. In this example, the method further includes the step of oxidizing the capping layer 6. The capping layer 6 combines with oxygen (O₂) to form a capping oxide film. That is, the titanium film combines with oxygen (O₂) to form a Ti oxide film. Accordingly, the capping layer 6 expands according to the oxidation to close gaps in the column structure of the barrier metal layer 5.

Next, a contact metal material 7 is deposited to gap-fill the contact hole. In this embodiment, the contact metal material 7 includes Al, Cu, W and the like.

Referring to FIG. 3D, the contact metal material 7 is planarized. A second metal line 8 is then formed on the entire upper surface of the resultant substrate. In one example embodiment, the planarization can be performed by a chemical mechanical polishing (CMP) process. The second metal line 8 can be formed of Al, Cu, W and the like produced by a sputtering method.

According to several embodiments, the capping layer can prevent a metal material (e.g., Al, Cu, and W) or a reaction gas (e.g., WF₆ and SiH₄) from infiltrating between barrier metal grains of the column structure in a subsequent step. Further, unoxidized titanium produces TiW to facilitate growth of tungsten grains, thereby producing a tungsten film having improved resistivity.

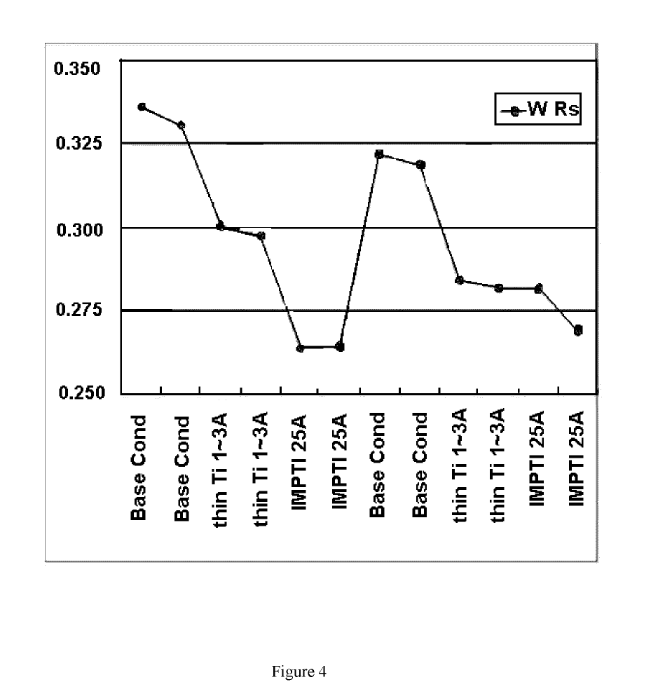

FIG. 4 depicts a graph illustrating sheet or contact resistance of a tungsten film. Specifically, FIG. 4 shows a comparison of sheet resistances from a general barrier layer and the tungsten film formed according to one or more of the embodiments disclosed herein. From FIG. 4, it can be appreciated that the sheet resistance decreases as the thickness of the titanium film increases.

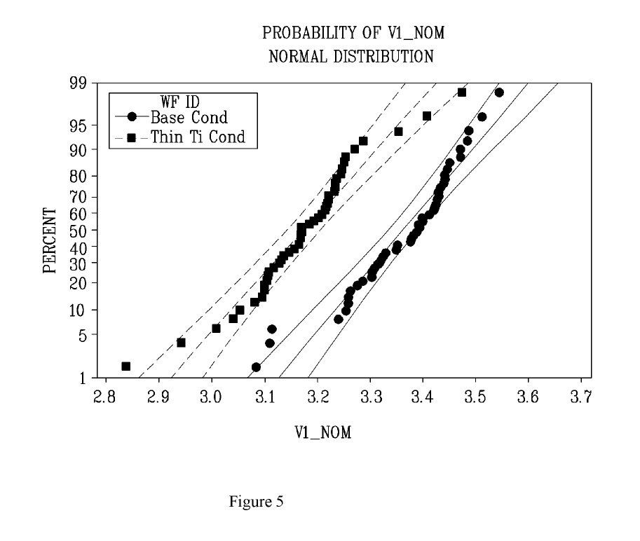

FIG. 5 depicts a graph showing DC test results of a contact hole illustrating the advantages of the teachings disclosed herein. Referring to FIG. 5, it can be appreciated that a wafer having a thin Ti film (“Tin TI Cond”) has DC 6% lower than that of a conventional embodiment (“Base Cond”).

As discussed above, a drawback of the conventional column structure of the titanium nitride (TiN) film can be overcome by a capping Ti film, thereby reducing contact resistance and preventing metal loss as set forth by the teachings disclosed herein. Further, it can be possible to produce a film having improved resistivity by growing grains of the tungsten as set forth by the teachings disclosed herein.

Although example embodiments of the present invention have been shown and described, changes might be made in these example embodiments. The scope of the invention is therefore defined in the following claims and their equivalents.

I claim:

1. A method for forming metal lines of a semiconductor device, comprising:
forming a first metal line on a semiconductor substrate;
forming an insulating film on the first metal line;
forming a contact hole in the insulating film;
sequentially forming a barrier metal layer and a capping layer on an upper surface of a resultant substrate;
oxidizing the capping layer to form a capping oxide film;
depositing a contact metal material on the resultant substrate;
planarizing the contact metal material to expose the insulating film; and
forming a second metal line on the insulating film.

2. The method according to claim 1, wherein sequentially forming a barrier metal layer and a capping layer is performed on an entire upper surface of a resultant substrate.

3. The method according to claim 1, wherein the contact hole is formed by forming a pattern of the contact hole with reactive ion etching (RIE) that uses a pattern as a mask to perform anisotropic etching and coats a photoresist on the insulating film.

4. The method according to claim 3, further comprising removing the photoresist through an ashing and cleaning process.

5. The method according to claim 1, wherein the barrier metal layer has a double structure of a titanium (Ti)/titanium nitride (TiN) film and a titanium nitride (TiN) film.

6. The method according to claim 1, wherein the barrier metal layer has a titanium nitride (TiN) film.

7. The method according to claim 1, wherein the capping layer is formed of titanium (Ti).

8. The method according to claim 6, wherein the capping layer has a thickness of about 20 Å.

9. The method according to claim 1, wherein the capping layer is oxidized by an oxygen (O₂) gas.

10. The method according to claim 1, wherein the contact metal material includes at least one of copper (Cu), tungsten (W) and aluminum (Al).

11. The method according to claim 1, wherein the capping layer is formed by a sputtering method.

12. The method according to claim 1, wherein the step of planarizing the contact metal material to expose the insulating film is performed by a chemical mechanical polishing (CMP) process.

13. The method according to claim 1, wherein the capping oxide film closes gaps in a column structure of the barrier metal layer.

14. The method according to claim 1, wherein contact resistance is reduced as a result of the capping oxide film.

15. The method according to claim 1, wherein defects in the barrier metal layer are reduced.
